(19) United States
(12) Patent Application Publication
(10) Pub. No.: US 2006/0002208 A1
(43) Pub. Date: Jan. 5, 2006

(54) Housing for a semiconductor device and semiconductor device testing system for testing the contacting for semiconductor devices positioned one above the other

(75) Inventor: Henning Hartmann, Tegernheim (DE)

Correspondence Address: MORRISON & FOERSTER LLP, 1650 TYSONS BOULEVARD, SUITE 300, MCLEAN, VA, 22102, US

(73) Assignee: INFINEON TECHNOLOGIES AG, Munchen (DE)

(21) Appl. No.: 11/170,752

(22) Filed: Jun. 30, 2005

(30) Foreign Application Priority Data
Jul. 1, 2004 (DE) 10 2004 031 997.9

(51) Int. Cl. G11C 29/00

(52) U.S. Cl. 365/201

(57) ABSTRACT

The invention relates to a housing for a semiconductor device and a novel semiconductor device testing system, in particular for testing the contacting of semiconductor devices positioned one above the other, which increases the parallelism during testing, is solved by the present invention in that recesses or notches, respectively, are provided in the housing for a semiconductor device, via which at least one internal contact line (bond wire) that connects an integrated circuit with external contacts (pins) can be contacted from outside, in particular for performing semiconductor device tests. The resulting advantage is that, for testing the semiconductor device or semiconductor module, respectively, not only the external contacts (pins), but also the recesses or notches, respectively, in the housing of the semiconductor device or semiconductor module, respectively, can be used for contacting.

### CLAIM FOR PRIORITY

This application claims the benefit of priority to German Application No. 10 2004 031 997.9 which was filed in the German language on Jul. 1, 2004, the contents of which are hereby incorporated by reference.

### TECHNICAL FIELD OF THE INVENTION

The invention relates to a housing for a semiconductor device, and to a semiconductor device testing system, in particular for testing the contacting of semiconductor devices positioned one above the other.

### BACKGROUND OF THE INVENTION

Semiconductor devices, e.g. integrated (analog or digital) computing circuits as well as semiconductor memory devices such as functional memory devices (PLAs, PALs, etc.) and table memory devices (e.g. ROMs or RAMs, in particular SRAMs and DRAMs), etc. are subject, in the course of their manufacturing process—e.g. in the semi-finished and/or finished state, before and/or after the incorporation in appropriate device modules, etc.—to comprehensive tests or functioning checks, respectively.

For the common manufacturing of a plurality of semiconductor devices, a so-called wafer (i.e. a thin disc manufactured of monocrystalline silicon) is used as a rule. The wafer is accordingly subject to a plurality of working processes, e.g. coating, exposure, etching, diffusion and implantation processes.

After termination of the working processes, the semiconductor devices are individualized by the wafer being, for instance, sawn apart or scratched and broken, so that the individual semiconductor devices or elements are then available for further processing.

After the finishing of the semiconductor devices (i.e. after the performing of the above-mentioned wafer processing steps), the semiconductor devices are subject to further testing processes at one or a plurality of (further) testing stations for instance, by means of appropriate (further) testing devices, the devices—that are finished, but still positioned on the wafer—may be tested appropriately (so-called disc tests).

After the sawing apart (ore the scratching, and breaking, respectively) of the wafer, the devices—which are then available individually—are loaded each individually in so-called carriers (i.e. a corresponding packing), whereupon the semiconductor devices—loaded into the carriers—may be subject to appropriate further testing processes at one or a plurality of (further) testing stations.

Correspondingly, one or a plurality of further tests may be performed (at appropriate further testing stations, and by using appropriate, further testing devices) e.g. after the incorporation of the semiconductor devices in the corresponding semiconductor device housings, and/or e.g. after the incorporation of the semiconductor device housing (together with the respective semiconductor devices incorporated therein) in appropriate electronic modules (so-called module tests).

During the manufacturing of a semiconductor device, a silicon substrate is consequently manufactured first of all in so-called front-end-processes, said silicon substrate comprising the desired memory cells or integrated circuits, respectively. After the finishing of the silicon substrates or chips, respectively, and their individualization in so-called back-end-processes, the electrical connections (contact pads) of the chips are connected (“bonded”) via electrical connecting lines (bond wires) with a contact frame so as to enable the electrical contacting of the silicon substrate with the periphery via external contacts or so-called pins. Subsequently, the chips connected with the contact frame are, as a rule, molded in a plastics housing along with the contact frame, so that a housed semiconductor device is the result. A plurality of such semiconductor devices may then be composed to form a semiconductor module. Alternatively, it is also possible that a number of semiconductor devices are composed to form a semiconductor module even prior to the molding in separate plastic housings and are molded together in a common housing subsequently only.

For instance, appropriate semiconductor devices such as SRAMs or DRAMS, or a DRAM with double data rate (DDR-DRAMs=Double Data Rate—DRAMs) may be inserted in an appropriate device module, with the electrical connections or pins of the semiconductor device being contacted with the corresponding module pads. After the incorporation of the semiconductor device, in particular after the soldering of the pins of the semiconductor device with the module pads, a test may be performed by means of an appropriate testing device on whether the pins of the semiconductor device safely contact the respective module pads. In the case of conventional semiconductor devices, the external contacts or pins are, in general, connected inside the device to one or a plurality of protective devices each comprising one or a plurality of diodes (e.g. an ESD structure comprising one or a plurality of diodes each connected to the supply voltage and/or ground connection).

During testing, relatively high voltages are applied to the pins, so that the diodes become conductive and then connect the pins in a low-resistance manner with the corresponding supply or ground connection, respectively. This avoids that—during the applying of high voltages—further devices connected with the pins are impacted with too high currents, this preventing a destruction of the further devices.

For testing whether a particular pin of the semiconductor device is safely contacting the corresponding module connection, current may be imposed upon the corresponding protection diode by the above-mentioned testing device via the corresponding module pad, whereafter the voltage dropping across the diode is measured. This means, an appropriate voltage may be applied by the testing device at the module pad, whereafter the current flowing through the diode is measured. When no or only very little current is flowing, it is detected that no or no sufficiently good contacting exists between the pin of the semiconductor device and the module pad.

As mentioned above, frequently a plurality of semiconductor devices are incorporated in one device module, wherein the semiconductor devices may be positioned side by side in one and the same plane. In order to increase the number of semiconductor devices that can be incorporated in a device module, in the case of so-called stacked modules the semiconductor devices are—for reasons of space—arranged, contrary thereto, in different planes. This is done in particular such that e.g. every two or more (e.g. three or four) semiconductor devices are positioned directly one above the other. The result of this is that e.g. 18 instead of only 9 semiconductor devices can be incorporated in a semiconductor module of particular size.

In so doing, all (active) outer contacts or pins of a top semiconductor device can be connected to corresponding (active) pins of the respective semiconductor device positioned therebelow (e.g. by means of appropriate soldering connections). An exception to this kind of contacting are, for instance, pins that are to be triggered separately, e.g. the device select pin or the chip select pin (CS pin) of the top semiconductor device which can be connected to a non-active pin of the bottom semiconductor device, or vice versa.

After the incorporation of the stacked semiconductor devices in a stacked module and the soldering of the corresponding pins with the corresponding module pads, it can be tested by means of an appropriate testing method whether the pins of the semiconductor devices are safely contacting the corresponding module pads. To this end, for instance, in accordance with the above-described method, a testing device imposes, via the module pad to be tested, and from there via the corresponding pin of the bottom and of the top semiconductor devices, a current upon the corresponding device protection diodes which are connected in parallel and are each connected with the corresponding pin of the top or bottom semiconductor devices. In so doing, the voltage dropping across the diodes is measured. This means, a corresponding voltage is applied by the testing device at the module pad to be tested, with the current flowing through the diodes being measured. If no or only very little current is flowing, a contacting fault is detected.

This conventional testing method has the advantage that a semiconductor module can only be contacted via its external contacts or pins, while the individual semiconductor devices of the module cannot be checked separately. Therefore, with conventional testing methods it is not—or only with relatively great effort and with a testing device having a very high measuring resolution—possible to detect that the pin of a semiconductor device is indeed contacting the corresponding module pad sufficiently well, not, however, the corresponding pin of another semiconductor device since a relatively high current may flow through the diode connected with the well-contacted pin. Neither—or only with relatively high effort—can it be detected with the known testing methods whether a soldering connection does indeed exist between the module pad and the corresponding pin, but that it is not of sufficiently good quality since it has, for instance, too high resistance. It is therefore desired that the individual semiconductor devices of a semiconductor module can individually be subject to a functioning check.

It is in particular during the manufacturing of DRAMs (Dynamic Random Address Memory) that the integrated circuits (chips) have to be checked or tested several times during the manufacturing process to ensure their correct functioning during later use. The costs for each individual testing step are adding up, in particular in volume production, to form a substantial portion of the overall production costs. Particular importance during the testing of DRAMs is attached to the checking of the semiconductor modules since this is, as a rule, the last major test insertion prior to the dispatching of the electronic modules, and since the majority of the application-relevant functions is checked here.

Previous solutions for increasing the parallelism with the checking of the semiconductor devices or semiconductor modules, respectively, have been substantially limited by the available resources of the testing device, in particular the number of the driver or input/output channels for operating the semiconductor module, on the one hand, and the purely physically required demand of space on the face for incorporating the semiconductor devices or semiconductor modules, respectively, to be tested, the so-called “load board” of the testing device for a plurality of modules contacted side by side in the testing device, on the other hand. With modern measures for increasing the parallelism, so-called test modes are frequently used, which place the device to be tested in a state that enables the operation with reduced testing resources. Thus, the first-mentioned problem of the limited number of driver or input/output channels for operation may be solved. The problem of the increased demand of space by the devices positioned side by side during testing remains, though.

### SUMMARY OF THE INVENTION

The present invention addresses the problem that the known housings of semiconductor devices or semiconductor modules have, so far, not enabled any other contacting of the connecting lines (bond wires) between the contacts (contact pads) of the integrated circuits and the external contacts of the semiconductor device or the semiconductor module, respectively, than via the external contacts of the semiconductor device or the semiconductor module, respectively, itself. The known housings are, as a rule—apart from the places at which the external contacts or pins of the semiconductor device or semiconductor module project—completely sealed.

The present invention provides a housing for a semiconductor device and a semiconductor device testing system, and in particular for testing the contacting of semiconductor devices positioned one above the other. The present invention also minimizes the costs accruing by the testing methods. In another embodiment of the present invention, there is contacting of the housed semiconductor device which enables a distinct increase of the parallelism of the testing method and thus provides a contribution to increasing the efficiency during device testing.

In one embodiment of the present invention, there is a housing for a semiconductor device, in particular a DRAM memory module, comprising at least one integrated circuit connected via internal electrical contact lines (bond wires) with external contacts (pins) for electrically contacting the integrated circuit with the periphery, wherein the housing comprises at least one recess or notch, respectively, via which at least one of the internal contact lines can be contacted from outside, in particular for performing semiconductor device tests.

From the lateral arrangement of contact notches in the housing for a semiconductor device according to the invention, there results the advantage that a plurality of semiconductor devices, also of semiconductor devices positioned one above the other, can be tested simultaneously in one testing device. The present invention thus solves the problem of the limited space available in the testing device for the semiconductor devices or semiconductor modules, respectively, to be tested.

Furthermore, the housing according to the invention has the advantage that the contact lines (bond wires) connecting the contacts (contact pads) of the integrated circuits with the external contacts (pins) of the semiconductor device or the semiconductor module, respectively, are not only contacted via the external contacts (pins) of the semiconductor device or semiconductor module, respectively, but can also be contacted directly via the recesses or notches, respectively, in the housing of the semiconductor device or semiconductor module, respectively. The notches serve preferably or exclusively the purpose of testing and exist in addition to the external contacts (pins) of the semiconductor device that are already available.

From this, there results the further advantageous effect that, for testing the semiconductor device or semiconductor module, respectively, not only the external contacts (pins), but also the recesses or notches, respectively, in the housing of the semiconductor device or semiconductor module, respectively, are available. The contacting of the contact lines (bond wires) from outside the semiconductor device is again not performed via the external contacts of the semiconductor device, but via the notches at the side face of the housing. Therefore, on the one hand, the individual semiconductor devices of a semiconductor module can be checked separately and directly. On the other hand, a higher parallelism of the testing method results therefrom since the checking of individual semiconductor devices of a semiconductor module can take place simultaneously.

The contacting of the contact lines of the semiconductor device from outside via notches or recesses, respectively, in the housing according to the invention further has the advantage that the corresponding contact lines cannot be contacted inadvertently since they are positioned in the recess of the notch and thus withdrawn from the main level of the surface of the semiconductor device. If the contact lines were running directly to the plane surface of the semiconductor device to make them accessible for the purpose of testing, an undesired contact or a short-circuit might possibly occur.

Another advantage of the present invention is that the costs accruing can be reduced by the testing method according to the invention in that the testing times are shortened and the parallelism of the testing method is increased.

In a further preferred embodiment of the present invention, the notches are provided at least partially in a side face and/or a front face of the housing. The contacting of the contact lines of the individual semiconductor devices from outside is then, again, not performed via the external contacts (pins) of the semiconductor device, which are frequently positioned at the bottom of the semiconductor device, but via the notches at the side face of the housing. Thus, the semiconductor devices may be stacked also within a semiconductor module and can nevertheless be contacted simultaneously and individually for performing testing methods.

Expediently, a major number of notches is provided in the housing, via which the contact lines of the semiconductor device can be contacted from outside. It is of particular advantage if only one contact line each can be contacted from outside via each notch. By that, a particular contact line can be assigned to each notch, so that a confusion or a short-circuit between the contact lines is excluded. Preferably, at least one notch is provided in the housing of the semiconductor device at least for each contact line that has to be contacted during the testing process. The notches may be produced at least partially by an inclination or recess at the lower and/or upper edge of the side face of the housing.

In a further preferred embodiment of the housing according to the invention, an electrical contact face is provided in the notch or recess, respectively, which is connected with the contact line to facilitate the contacting of the corresponding contact line from outside. The electrical contact face in the notch or recess of the housing is preferably designed in the form of an electrically conductive face that is sufficiently large to be reliably contacted from outside via appropriate contact takers.

The contact lines (bond wires) can be contacted via the notches in the housing of the semiconductor device in that either branch lines run from the corresponding contact line to the electrical contact in the notch, or the respective contact line runs from the integrated circuit via the electrical contact face in the notch and from there on to the outer contacts (pins) of the semiconductor device or semiconductor module, respectively.

The outer contacts (pins) of the semiconductor devices may be arranged at the bottom and/or at the top of the housing. To ensure a reliable and easy contacting of the semiconductor devices positioned one above the other, the outer contacts are preferably designed as ball pins. These are contacted with one another during the stacking of the individual semiconductor devices and are, for instance, soldered to each other.

The above-mentioned objects are further solved by a testing system for checking the functioning of semiconductor devices or semiconductor modules, respectively, in particular of DRAM memory modules, comprising at least one integrated circuit in a housing, wherein the integrated circuit is connected, via internal electrical contact lines, with external contacts for electrically contacting the integrated circuit with the periphery, wherein, for performing a semiconductor device test, at least one internal contact line of the semiconductor device is contacted from outside by contact takers of the testing system via recesses or notches, respectively, in the housing of the semiconductor device.

The testing system according to the invention is in particular suited for checking the functioning of semiconductor devices or semiconductor modules, respectively, having an inventive housing of the kind described above, and has the advantage that the contact lines (bond wires) connecting the contacts (contact pads) of the integrated circuits with the external contacts (pins) of the semiconductor device or the semiconductor module, respectively, cannot only be contacted via the external contacts (pins) of the semiconductor device or semiconductor module, respectively, but also directly via the recesses or notches, respectively, in the housing of the semiconductor device or semiconductor module, respectively. The result of this is that, apart from the external contacts (pins), the recesses or notches, respectively, in the housing of the semiconductor device or the semiconductor module, respectively, can also be used for testing the semiconductor device or semiconductor module, respectively.

The contacting of the contact lines (bond wires) from outside of the semiconductor device or semiconductor module, respectively, is, with the testing system according to the invention, not or not exclusively performed via the external contacts (pins) of the semiconductor device, but via the contact takers that engage in the notches at the side face of the housing and thus establish an electrical connection between the testing device and the contact lines of the semiconductor device or semiconductor module, respectively. Thus, individual semiconductor devices of a semiconductor module can be checked separately and directly.

The separate checkability of individual semiconductor devices of a semiconductor module also results in an increased parallelism of the testing method since the checking of the semiconductor devices can take place simultaneously. The contactability of individual contact lines (bond wires) of the semiconductor devices in a semiconductor module further enables more contact combinations, which improves the diversification of the testing methods.

By the introduction of a further dimension, namely the height, during the positioning of the semiconductor devices one above the other in the testing device, the parallelism of the testing methods is increased. Thus, the number of semiconductor devices that can be tested simultaneously, e.g. DRAM devices, is no longer restricted only by the breadth and depth of the load board (connection of every individual DRAM to the testing system). Corresponding to the number of the stacked devices, a multiplication of the parallelism during the testing of semiconductor devices is achieved.

In a preferred embodiment of the present invention, the contacting is performed by contact takers of the testing system with the contact lines of the semiconductor device at least partially via notches in a side face of the housing. The contacting of the contact lines of the individual semiconductor devices from outside by the contact takers of the testing system is then, again, not or not only performed via the external contacts of the semiconductor device, which are frequently arranged at the bottom of the semiconductor module, but via the notches at the side face of the housing. Thus, the testing system according to the invention is capable of simultaneously and individually contacting also stacked semiconductor devices and of performing functioning tests in parallel on one single testing place or socket, respectively, of the testing device.

To this end, the testing system and in particular its contact takers are expediently designed such that a number of semiconductor devices positioned one above the other can be contacted simultaneously, and thus a number of semiconductor devices can be tested in parallel. Furthermore, the testing device may be provided with such a number of contact takers and the face (load board) of the testing device for incorporating the semiconductor devices to be tested may be designed such that a number of stacked semiconductor devices can be contacted simultaneously and can be tested in parallel.

Advantageously, a number of contact takers are provided at the testing device, the contact takers contacting the contact lines of the semiconductor device via notches at least at two side faces and/or front faces of the housing of the semiconductor device. As has been described above, in the inventive housing of the semiconductor device or semiconductor module, respectively, the notches or recesses, respectively, for the contacting by the testing system are preferably arranged in a side face and/or a front face of the housing. The contact takers of the testing system can then each contact a contact line of the semiconductor device via a notch in the housing of the semiconductor device or semiconductor module, respectively.

In another preferred embodiment of the present invention, a number of contact takers are provided, each contacting a stack of semiconductor devices positioned one above the other, so that a number of stacks of semiconductor devices positioned one above the other can be tested simultaneously.

It is of particular advantage when the contact takers of the testing system have a shape that is complementary to the notches in the housing of the semiconductor device or semiconductor module, respectively. Both the shapes of the contact takers of the testing device and the shape of the notches in the housing of the semiconductor device or semiconductor module, respectively, can be designed differently and be coordinated such that, on the one hand, a safe contacting of the contact takers with the contact lines (bond wires) is ensured and a confusion of the contacts is excluded.

### BRIEF DESCRIPTION OF THE DRAWINGS

In the following, the invention will be explained in more detail with respect to preferred embodiments with reference to the enclosed drawings. The drawing shows:

FIG. 1 shows a bottom view of a semiconductor device with a housing according to a preferred embodiment of the present invention.

FIG. 2 shows a side view of the semiconductor device illustrated in FIG. 1, with a housing according to a preferred embodiment of the present invention.

FIG. 3 shows a sectional view along the cross-section axis A illustrated in FIG. 1, through the semiconductor device illustrated in FIGS. 1 and 2, with a housing according to a preferred embodiment of the present invention.

FIG. 4 shows a perspective representation of a testing system for testing semiconductor devices according to a preferred embodiment of the present invention.

### DETAILED DESCRIPTION OF THE INVENTION

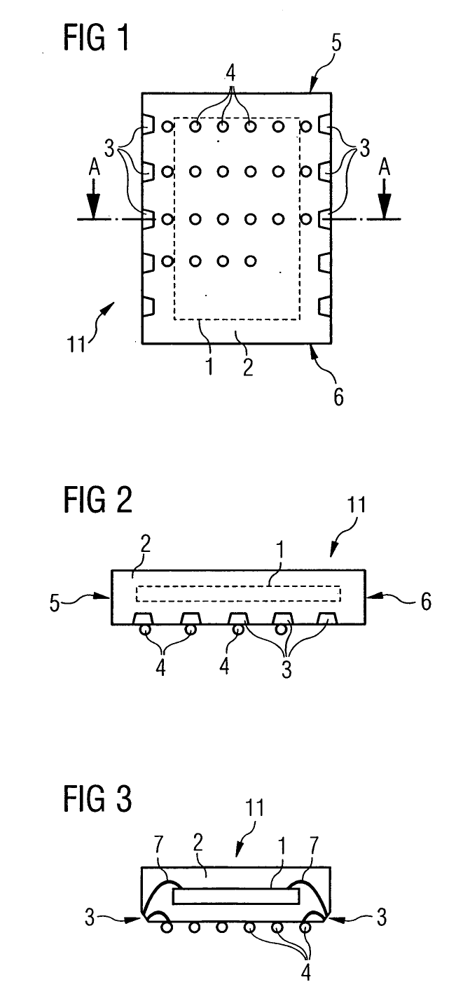

FIG. 1 shows a schematic representation of a bottom view of a semiconductor device 11 with a housing 2 in a preferred embodiment of the present invention. The semiconductor device 11 comprises an integrated circuit 1, e.g. a DRAM memory chip, on which memory cells are accommodated. The integrated circuit 1 is molded in a housing 2 of plastics, the housing surrounding the integrated circuit 1 completely. The housing 2 has substantially the shape of a flat cuboid and hence comprises side faces, front faces 4 and 5, a top and a bottom.

At the bottom of the housing 2, external contacts in the form of ball pins 4 are arranged, via which the integrated circuit 1 is adapted to be connected to the periphery. To this end, the internal contacts (contact pads) of the integrated circuit 1 each are connected with the external contacts (ball pins) 4 of the semiconductor device 11 via electrical contact lines (bond wires). In the side faces of the housing 2, a number of recesses or notches 3, respectively, are provided, via which the contact lines are adapted to be contacted from outside, as will be explained in more detail in the following with reference to FIG. 3.

FIG. 2 shows a schematic representation of a side view of the semiconductor device 11 illustrated in FIG. 1. This view clearly reveals that the notches 3 are arranged almost over the entire length of the side face of the housing 2 at the lower edge thereof. FIG. 3 shows a sectional view along a cross-section axis A through the semiconductor device 11 illustrated in FIGS. 1 and 2, indicated in FIG. 1 by a dot and dash line. FIG. 3 reveals that the integrated circuit 1 is connected with the external contacts (ball pins) 4 of the semiconductor device 11 via a plurality of electrical contact lines (bond wires) 7.

The contact lines (bond wires) 7 each run from an internal contact (contact pad) of the integrated circuit 1 to a notch 3 at the outer edge of the housing 2, and a further contact line runs from the notch 3 on to an external contact 4 of the semiconductor device 11. This way, the contact lines 7 can apart from the possibility of being contacted via the external contacts (ball pins 4)—also be contacted directly from outside via the notches 3 in the housing 2 of the semiconductor device 11, in particular for the purposes of testing.

As is shown in FIG. 3, the notches are produced at least partially by an inclination at the lower edge of the side face of the housing 2. In the embodiment of the semiconductor device 11 shown in the drawings, one contact line 7 each can be contacted via each notch 3 from outside. By that, each notch 3 can be assigned a particular contact line 7, so that a confusion or a short circuit between the contact lines 7 is excluded both during the testing process and also afterwards. To this end, at least for each contact line 7 that has to be contacted during the testing process, one notch 3 is provided in the housing 2 of the semiconductor device 11.

The contacting of the contact lines 7 of the individual semiconductor devices from outside is performed, during the testing process, not or not exclusively via the external contacts (ball pins) 4 provided at the bottom of the semiconductor device 11, but via the notches 3 at the side face of the housing 2. Therefore, a plurality of semiconductor devices 11 can be stacked and nevertheless remain contactable simultaneously and individually via the notches 3 in the side faces of the housing 2 for performing testing methods.

In the recess or notch 3, respectively, there is provided an electrical contact face that is connected with the contact line 7 to facilitate the contacting of the respective contact line from outside. The electrical contact faces in the notches 3 in the housing 2 each are so large that they can be contacted reliably from outside via corresponding contact takers of a testing device.

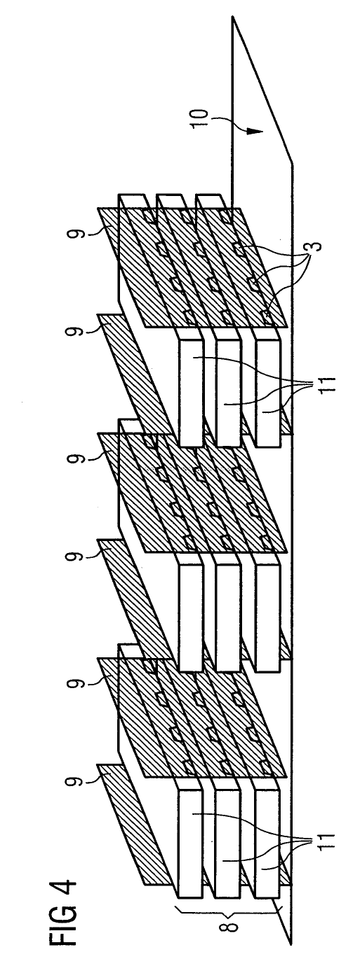

FIG. 4 shows a perspective representation of a testing system for testing semiconductor devices according to a preferred embodiment of the present invention. The inventive testing system is in particular suited for checking the functioning of or for testing semiconductor devices 11 with an inventive housing of the kind described above. The testing system comprises a testing device with a so-called load board 10, i.e. a face for arranging the semiconductor devices 11 to be tested. A plurality of sockets (not illustrated) are arranged on the load board 10, by which the semiconductor devices 11 to be tested can be contacted via the external contacts for testing purposes. One stack 8 each of semiconductor devices 11 positioned one above the other is positioned on each socket of the testing device.

The testing system is provided with a number of contact takers 9 that are designed to be adapted to simultaneously contact a number of semiconductor devices positioned one above the other via the notches 3 in the side faces of the housing 2. To this end, one contact taker 9 each is provided at each side of a stack 8 of semiconductor devices 11 such that the contact lines 7 of the semiconductor device 11 can each be contacted via the two side faces by the notches 3 in the housing 2 of the semiconductor device 11. Thus, the testing system is capable of simultaneously contacting a number of stacked semiconductor devices 11 and of testing them in parallel.

The contact lines (bond wires) 7 that contact the internal contacts (contact pads) of the integrated circuits 1 with the external contacts (ball pins) 4 of the semiconductor device 11 are thus contacted by the testing system not only via the external contacts 4 of the semiconductor device 11, but in particular directly via the recesses or notches 3, respectively, in the housing 2 of the semiconductor device 11. Thus, the number of semiconductor devices 11, e.g. DRAM devices, that can be tested simultaneously is, corresponding to the number of the stacked semiconductor devices 11, increased and a multiplication of the parallelism is achieved with the testing method.

In the embodiment of the inventive testing device illustrated in FIG. 4, the electrical contacting of the semiconductor devices 11 is performed by contact takers 9 that are connected with the contact lines 7 of the semiconductor device 11 via the notches 3 in the side faces of the housing 2. It is, however, also possible that the electrical contacting of the semiconductor devices 11 is performed by contact takers 9 that are connected with the contact lines 7 of the semiconductor device 11 via notches 3 in the front faces 5, 6 and/or at the top of the housing 2. The In the present invention, the contacting of the contact lines 7 of the individual semiconductor devices is performed from outside by the contact takers of the testing system and thus not or not exclusively via the external contacts 4 at the bottom of the semiconductor device 11, but via the notches 3 at the side face of the housing 2. Thus, the inventive testing system is capable of contacting stacked semiconductor devices 11 individually and simultaneously, and of performing functioning checks in parallel on one single socket of the testing device.

What is claimed is:

1. A housing for a semiconductor device, comprising at least one integrated circuit connected via internal electrical contact lines with external contacts for electrically contacting the integrated circuit with the periphery, wherein
the housing comprises at least one recess or notch, respectively, via which at least one of the internal contact lines is configured to be contacted from outside for performing semiconductor device tests.

2. The housing according to claim 1, wherein the notches are provided at least partially in a side face and/or a front face of the housing.

3. The housing according to any of claims 2, wherein a number of notches is provided in the housing, via which the contact lines are configured to be contacted from outside.

4. The housing according to claim 1, wherein one contact line each is configured to be contacted from outside via each notch.

5. The housing according to claim 1, wherein the notches are produced at least partially by an inclination or recess, respectively, at the lower and/or upper edge of the side face of the housing.

6. The housing according to claim 1, wherein the outer contacts are arranged at the bottom and/or at the top of the housing and are designed as ball pins.

7. The housing according to claim 1, wherein an electrical contact in the form of an electrically conductive face is provided in the notch and is connected with the contact line.

8. The housing according to claim 7, wherein the contact lines run from the integrated circuit via the electrical contact in the notch to the external contacts.

9. A testing system for checking functioning of semiconductor devices, comprising a housing, wherein the semiconductor device comprises at least one integrated circuit that is connected via internal electrical contact lines with external contacts for electrically contacting the integrated circuit with a periphery, the testing system performing a semiconductor device test, at least one internal contact line of the semiconductor device is contacted from outside by contact takers of the testing system via recesses or notches, respectively, in the housing of the semiconductor device.

10. The testing system according to claim 9, wherein the contact takers of the testing system contact the contact lines of the semiconductor device at least partially via notches in a side face of the housing.

11. The testing system according to claim 9, wherein the contact takers thereof are designed to simultaneously contact a number of semiconductor devices positioned one above another, so that a number of semiconductor devices can be tested simultaneously.

12. The testing system according to claim 9, wherein the contact takers of the testing system each contact one contact line via a notch that is preferably arranged in a side face and/or a front face of the housing.

13. The testing system according to claim 12, wherein a number of contact takers are provided, each of which contacts the contact lines of the semiconductor device at least at two side faces and/or front faces of the housing via notches.

14. The testing system according to claim 9, wherein a number of contact takers are provided, each of which contact a stack of semiconductor devices positioned one above another, so that a number of stacks of semiconductor devices positioned one above the other can be tested simultaneously.

15. The testing system according to claim 9, wherein the contact takers of the testing system have a shape that is complementary to the notches in the housing of the semiconductor device.
